(19) United States
(12) Patent Application Publication
(10) Pub. No.: US 2014/0300064 A1
(43) Pub. Date: Oct. 9, 2014

(54) MEMBER FOR SEMICONDUCTOR MANUFACTURING DEVICE

(71) Applicants: Mitsuharu Inaba, Hyogo (JP); Hiroki Yokota, Hyogo (JP); Keisuke Yamada, Hyogo (JP)

(72) Inventors: Mitsuharu Inaba, Hyogo (JP); Hiroki Yokota, Hyogo (JP); Keisuke Yamada, Hyogo (JP)

(73) Assignee: TOCALO CO., LTD., Hyogo (JP)

(21) Appl. No.: 14/355,085

(22) PCT Filed: Apr. 11, 2012
(86) PCT No.: PCT/JP2012/059860

§ 371 Date: Apr. 29, 2014

(30) Foreign Application Priority Data
Nov. 2, 2011 (JP) 2011-240856

(51) Int. Cl. H01L 21/683

(52) U.S. Cl. CPC H01L 21/6833; H01L 2221/683
USPC 279/128

(57) ABSTRACT

Provided is a member for semiconductor manufacturing device which hardly causes component contamination and is capable of sufficiently reducing generation of particles in a semiconductor manufacturing device. A spray coating is formed by spraying a ceramic onto a mounting member of a transfer arm, and laser beam is irradiated to the spray coating to remelt and resolidify the ceramic composition for modification to thereby form a high-strength ceramic layer made from a ceramic recrystallized material and having a net-like crack, whereby particles dropped out from the mounting member due to external factors in a semiconductor manufacturing device are reduced to an extent not affecting a semiconductor manufacturing process.

### TECHNICAL FIELD

The present invention relates to various kinds of members which are incorporated into a semiconductor manufacturing device, and more particularly to a member for semiconductor manufacturing device in which a coated ceramic spray coating is remelted and resolidified to improve mechanical strength of a surface layer thereof.

### BACKGROUND ART

There are a wide range of devices involved in the manufacture of semiconductors including an etching devices, a CVD devices, a PVD devices, a resist coating devices, an exposure devices and so on. Since presence of particles generated in these various kinds of devices affects the quality and yield of products, reduction of such particles is absolutely necessary. The semiconductor manufacturing process continues to be downsized, and hence generation of very fine particles, which have not been mentioned heretofore, is seen as a problem.

There are various sources of generating particles. In various members for semiconductor manufacturing device constituting the semiconductor manufacturing device, particles are generated at a surface contacting with a wafer. For example, particles are generated at a surface of an electrostatic chuck for holding a wafer in the etching device, which are backside particles adhered to the back surface of the wafer. As means for reducing such particles is known an electrostatic chuck wherein a surface of the chuck is embossed to form a plurality of projections on the surface and the edges of these plural projections are formed into a curved shape (see, for example, Patent Document 1).

In Patent Document 2, a portion contacting with a wafer in a transfer arm for transferring the wafer is made from a ceramic sintered material, and the surface thereof is rendered into a surface roughness of 0.2˜0.5 μm in terms of Ra value to suppress damages due to slipping or collision of the wafer. When the surface roughness is less than 0.2 μm, the wafer is easily slipped to generate damages due to collision between the wafer and the transfer arm, while when the surface roughness exceeds 0.5 μm, particles are easily generated due to the roughness.

### PRIOR ART DOCUMENTS

### Patent Documents

Patent Document 1: JP-A-2009-60035

Patent Document 2: JP-A-H07-22489

### SUMMARY OF THE INVENTION

### Problems to be Solved by the Invention

To the electrostatic chuck are applied forces of collision due to desorption of the wafer, friction due to thermal expansion and shrinkage of the wafer, pressing of the wafer and so on. When a plurality of projections are provided on the surface of the member as described in Patent Document 1, the wafer is necessary to be supported on smaller surfaces, and hence applicable force is relatively small, which may be not corresponded to the above applied forces. In order to improve production efficiency, it is necessary to increase the speed of the transfer arm. As the speed of the transfer arm becomes faster, forces tremblingly contacting with the wafer are applied by minute vibrations associated therewith, or forces contacting with the wafer are increased at the time of driving and stopping. In Patent Document 2, the behavior of the wafer is merely regulated by making the surface of the ceramic sintered material to a predetermined surface roughness, and therefore the previously mentioned forces cannot be borne. Further, stronger forces may be applied to members for semiconductor manufacturing device other than the electrostatic chuck and transfer arm, so that it is difficult to obtain an effect of sufficiently reducing particles in the methods of Patent Documents 1 and 2. In addition, when using the ceramic sintered material as in Patent Document 2, it is difficult to cope with a large-size member, and an impurity component such as sintering aid or the like is required, and use of a resin or a wax material for adhesion is required, which have also a problem that component contamination is caused and production cost is increased.

On the other hand, it is considered that particles are reduced by coating the surface of the member for semiconductor manufacturing device with a ceramic spray coating. As compared to the use of the ceramic sintered material, the ceramic spray coating is easy to cope with a larger member, and is free from the impurity component such as sintering aid, and does not require the adhesion by using the resin or wax material, so that there is no component contamination and the manufacture can be performed at lower costs. Therefore, it is increasingly expected to apply the ceramic spray coating to members for semiconductor manufacturing device despising component contamination. However, since the ceramic spray coating has a mechanical strength lower than that of the sintered material, particles may be generated if various forces as described above are applied, and currently the merit thereof cannot be utilized.

In view of the above-mentioned problems of the conventional techniques, it is an object of the present invention to provide a member for semiconductor manufacturing device hardly causing component contamination and capable of sufficiently reducing generation of particles in a semiconductor manufacturing device.

### Means for Solving Problems

The following technical means are taken for achieving the above object.

The present invention provides a member for semiconductor manufacturing device comprising a base member for forming a semiconductor manufacturing device, and a ceramic spray coating applied on a surface of the base member, characterized in that a surface layer of the ceramic spray coating is provided with a high-strength ceramic layer for reducing particles dropped out from the member for semiconductor manufacturing device due to external factors in the semiconductor manufacturing device to an extent not affecting a semiconductor manufacturing process, and the high-strength ceramic layer is made from a ceramic recrystallized material formed by spraying a ceramic onto the surface of the base member to form a thermal spray coating and then irradiating the surface thereof with a laser beam or an electron beam to remelt and resolidify a ceramic composition of the surface layer of the thermal spray coating for modification, and a net-like crack is formed in the high-strength ceramic layer.

The ceramic spray coating coated in the member for semiconductor manufacturing device according to the present invention is a coating formed by melting a ceramic spraying powder by a plasma flame or the like and spraying the melted powder to the surface of the base member to deposit melted particles on the surface thereof. In the present invention, the high-strength ceramic layer is further formed on the surface layer of the coating, and therefore the member for semiconductor manufacturing device can endure actions of various forces from a wafer or the like. Thus, particles dropped out from the member for semiconductor manufacturing device can be reduced to an extent not affecting the semiconductor manufacturing process, and generation of particles can be sufficiently reduced. Further, since the ceramic spray coating is used, the application of the present invention is not limited within the size of the member for semiconductor manufacturing device, while there is no component contamination because of the absence of impurity components, and the manufacture can be performed at lower costs.

The ceramic spray coating obtained by depositing particles at a melted state is known to significantly vary in the mechanical strength of the coating depending on the strength of bonding force or presence of pores at a boundary between the particles, presence/absence and amount of non-bonding particles, presence of particles not fully melted, and so on. Thus, the high-strength ceramic layer is made of the ceramic recrystallized material modified by remelting and resolidifying the ceramic composition as in the present invention, whereby a dense layer structure is obtained, and particles dropped out from the member for semiconductor manufacturing device can be surely reduced. Further, since the net-like crack is formed in the high-strength ceramic layer, the net-like crack acts as a buffer mechanism to thermal stress applied to the high-strength ceramic layer, so that breakage and peeling of the high-strength ceramic layer can be prevented.

It is preferable that each of at least 90% network regions among many network regions constituting the net-like crack has a size falling within an imaginary circle having a diameter of about 1 mm. In this case, the buffer mechanism to thermal stress can be surely effected.

It is preferable that the crack extends to a non-recrystallized layer in the ceramic spray coating. When the crack extends to the non-recrystallized layer in the ceramic spray coating, the action as a buffer mechanism to thermal stress applied on the high-strength ceramic layer can be enhanced to improve the effect of preventing breakage or peeling of the high-strength ceramic layer.

It is preferable that an opening portion of the crack is sealed because dropping out of particles through the cracks can be prevented. In this case, a substance for sealing includes inorganic substances such as SiO₂ and the like, and organic substances such as an epoxy resin, a silicon resin and the like.

The thickness of the high-strength ceramic layer is preferable to be not more than 200 μm. The layer thickness of 200 μm is sufficient for reducing coating particles dropped out from the ceramic spray coating. In order to obtain the layer thickness exceeding the above value, it is required to increase output of the laser beam or electron beam or to take an extended scanning time, leading to poor efficiency.

The surface roughness of the high-strength ceramic layer is preferable to be not more than 2.0 μm in terms of Ra value. When the surface roughness is in such a range, action of an excessively strong force on the high-strength ceramic layer can be prevented, for example, even if the wafer is rubbed.

For the ceramic-thermal spray coating can be employed a variety of compounds. As such a compound are included one or more compounds selected from the group consisting of oxide-based ceramics, nitride-based ceramics, carbide-based ceramics, fluoride-based ceramics and boride-based ceramics. As the oxide-based ceramic is preferable either one of alumina and yttria or a mixture thereof.

As the particles capable of being reduced in the present invention are mentioned backside particles generated at a back surface of a wafer or a glass base member, for example, when the wafer or the glass base member comes into contact with the ceramic spray coating. In this case, local elevation of the wafer or the glass base member, decrease in the flatness of the wafer or the glass base member, and decrease in degree of adhesion between the wafer or the glass base member and the member for semiconductor manufacturing device can be suppressed to reduce occurrence of defects resulted from the particles.

As the member for semiconductor manufacturing device are mentioned a wafer gripping member and a glass base member gripping member. By applying the present invention to these members can be manufactured products having an extremely high quality in the semiconductor manufacturing process.

### Effects of the Invention

As mentioned above, according to the present invention, component contamination is hardly generated because the ceramic spray coating is used, while the high-strength ceramic layer made of the ceramic recrystallized material is formed on the surface layer of the ceramic-thermal spray coating, so that particles dropped out from the member for semiconductor manufacturing device can be reduced to an extent not affecting the semiconductor manufacturing process, and generation of particles can be sufficiently reduced.

### BRIEF DESCRIPTION OF THE DRAWINGS

FIG. 1(a) is a schematic view showing a state of incorporating a transfer arm according to one embodiment of the present invention into a semiconductor manufacturing device, and FIG. 1(b) is a perspective view of the transfer arm.

FIG. 2 is a schematically sectional view of a mounting member in the vicinity of its surface.

FIG. 3(a) is a schematically sectional view of a mounting member coated with an Al₂O₃ spray coating and subjected to finish grinding, and FIG. 3(b) is a schematically sectional view after the irradiation of laser beam.

FIG. 4 is a process chart for adjusting surface roughness.

FIG. 5 is a schematically sectional view of a mounting member according to another embodiment in the vicinity of its surface.

FIG. 6(a) is an electron microscope photograph of a surface of a test piece 1, and FIG. 6(b) is an electron microscope photograph of a cross section of a surface layer thereof.

FIG. 7(a) is an electron microscope photograph of a surface of a test piece 2, and FIG. 7(b) is an electron microscope photograph of a cross section of a surface layer thereof.

FIG. 8(a) is an X-ray analysis chart of a surface layer of Al₂O₃ spray coating in the test piece 1, and FIG. 8(b) is an X-ray analysis chart of a surface layer of Al₂O₃ spray coating in the test piece 2.

FIG. 9(a) is a chart showing surface roughness of Al₂O₃ spray coating in the test piece 1, and FIG. 9(b) is a chart showing surface roughness of Al₂O₃ spray coating in the test piece 2.

FIG. 10(a) shows test results of the test piece 1 and the test piece 2 by abrasion test, and FIG. 10(b) shows test results of the test piece 1 and the test piece 2 by hardness test.

### EMBODIMENTS FOR CARRYING OUT THE INVENTION

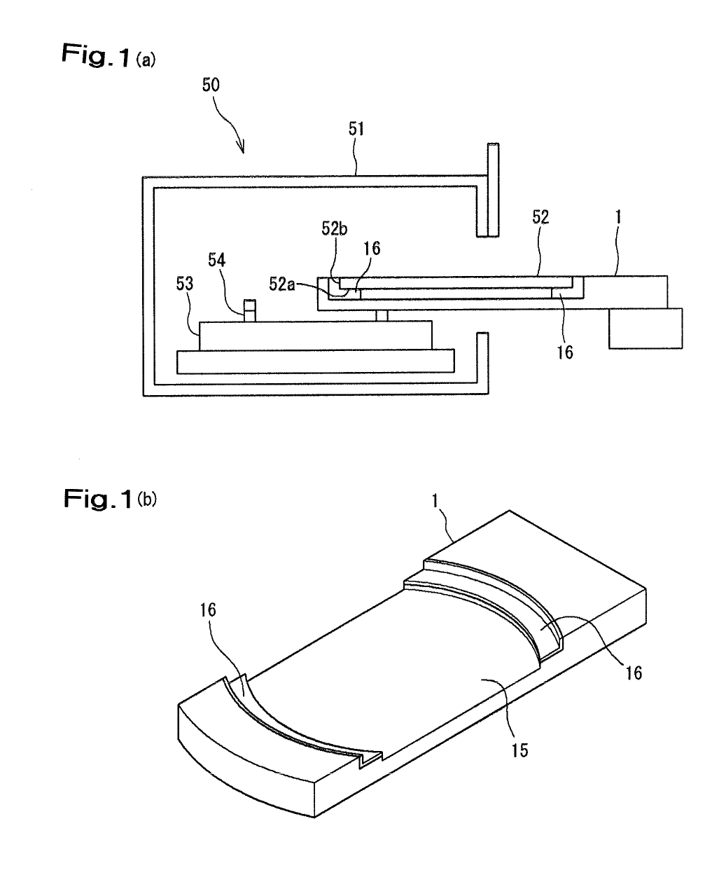

Embodiments of the present invention will be described below with reference to the drawings. FIG. 1(a) is a schematic view showing a state of incorporating a transfer arm i (member for semiconductor manufacturing device) according to one embodiment of the present invention into a semiconductor manufacturing device 50, and FIG. 1(b) is a perspective view of the transfer arm 1. As shown in FIG. 1, an electrostatic chuck 53 for holding a wafer 52 is disposed in a process chamber 51. When the wafer 52 is lifted from the electrostatic chuck 53 by a lifter pin 54, the transfer arm 1 is put into the chamber below the wafer 52 and then the lifter pin 54 is lowered to place the wafer 52 on the transfer arm 1, and thereafter the transfer arm 1 is removed from the process chamber 51 to transfer the wafer 52.

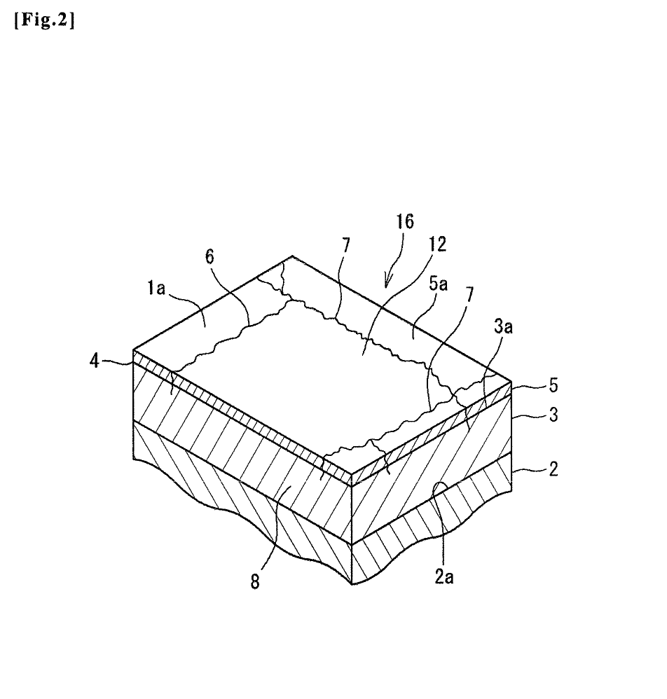

The transfer arm 1 is made of stainless steel, an aluminum alloy or the like, and has a long-plate shape as a whole. A concave holding portion 15 for holding the wafer 52 is formed in the transfer arm 1. At both ends of the holding portion 15 are disposed mounting members 16 of L-shaped cross section constituting a part of the transfer arm 1, respectively. The wafer 52 is actually placed on the mounting members 16 so as to contact an edge portion 52a and a side surface 52b of the back surface of the wafer 52 therewith. FIG. 2 is a schematically sectional view of the mounting member 16 in the vicinity of its surface. The mounting member 16 is constructed with a base member 2 made of stainless steel, an aluminum alloy or the like, and a ceramic spray coating 3 coated on a surface 2a of the base member 2 contacting with the wafer 52.

The ceramic spray coating 3 of this embodiment is an Al₂O₃ spray coating 3. The Al₂O₃ spray coating 3 is formed by roughening the surface of the base member 2 through blasting, and then spraying Al₂O₃ spraying powder onto the roughened surface 2a of the base member 2 through an air plasma spraying method. The spraying method for obtaining the Al₂O₃ spray coating 3 is not limited to the air plasma spraying method, but may be a reduced pressure plasma spraying method, a water plasma spraying method, or a high-speed and low-speed flame spraying method.

As the Al₂O₃ spraying powder are employed ones having a particle size range of 5 to 80 μm. When the particle size is less than 5 μm, the fluidity of the powder is deteriorated and the powder cannot be stably supplied, and hence the thickness of the coating becomes non-uniform, while when the particle size exceeds 80 μm, the coating is formed before the powder is fully melted, and made excessively porous, leading to rough coating quality.

The thickness of the Al₂O₃-thermal spray coating 3 is preferable to be a range of 50 to 2000 μm. When the thickness is less than 50 μm, the uniformity of the spray coating 3 is deteriorated and the coating function cannot be sufficiently developed, while when it exceeds 2000 μm, the mechanical strength is lowered due to the influences of residual stress in the coating, leading to breakage or peeling of the spray coating 3.

The Al₂O₃ spray coating 3 is a porous body, and the average porosity thereof is preferable to be a range of 5 to 10%. The average porosity varies depending on a spraying method and spraying conditions. When the porosity is less than 5%, residual stress existing in the Al₂O₃ spray coating 3 is increased, leading to lower the mechanical strength. When the porosity exceeds 10%, various kinds of gases used in the semiconductor manufacturing process are easily penetrated into the Al₂O₃ spray coating 3, and the durability of the spray coating 3 is deteriorated.

In this embodiment, Al₂O₃ is employed as a material of the ceramic spray coating 3, but other oxide-based ceramics, nitride-based ceramics, carbide-based ceramics, fluoride-based ceramics, boride-based ceramics and mixtures thereof may be employed. As a concrete example of other oxide-based ceramics are included TiO₂, SiO₂, Cr₂O₃, ZrO₂, Y₂O₃ and MgO. As the nitride-based ceramics are included TiN, TaN, AlN, BN, Si₃N₄, MN and NbN. As the carbide-based ceramics are included TiC, WC, TaC, B₄C, SiC, HfC, ZrC, VC and Cr₃C₂. As the fluoride-based ceramics are included LiF, CaF₂, BaF₂ and YF₃. As the boride-based ceramics are included TiB₂, ZrB₂, HfB₂, VB₂, TaB₂, NbB₂, W₂B₅, CrB₂ and LaB₆.

In a surface layer 4 of the Al₂O₃ spray coating 3 coated on the mounting member 16 is formed a high-strength ceramic layer 5. The high-strength ceramic layer 5 is the most characteristic part of this embodiment, and is a ceramic recrystallized material formed by modifying porous Al₂O₃ in the surface layer 4 of the Al₂O₃ spray coating 3. The high-strength ceramic layer 5 is an Al₂O₃ recrystallized material formed by irradiating laser beam onto the Al₂O₃ spray coating 3 to heat porous Al₂O₃ in the surface layer 4 of the spray coating 3 to its melting point or higher, and remelting and resolidifying it for modification.

The crystal structure of the Al₂O₃ spraying powder is α-type, and the powder is sufficiently melted in a flame, collided with the base member 2 to render into a flat shape, and rapidly solidified to form the Al₂O₃ spray coating 3 having a γ-type crystal structure. The Al₂O₃ spray coating 3 is substantially γ-type, but still contains α-type crystal captured while being scarcely melted in the flame and not formed into a flat shape even in the collision with the base member 2. Therefore, the crystal structure of the Al₂O₃ spray coating 3 before the irradiation of laser beam is in a mixed state of α-type and γ-type. The crystal structure of the Al₂O₃ recrystallized material forming the high-strength ceramic layer 5 is almost only α-type.

The Al₂O₃ spray coating 3 is a porous body as described above and has a stacked structure of many Al₂O₃ particles, wherein boundaries exist between Al₂O₃ particles. These boundaries are eliminated by irradiating laser beam to remelt and resolidify the surface layer 4 of the Al₂O₃ spray coating 3, and the number of pores is decreased associated therewith. Therefore, the high-strength ceramic layer 5 formed of the Al₂O₃ recrystallized material has a very dense layer structure. Since the high-strength ceramic layer 5 forming the surface layer 4 of the Al₂O₃ spray coating 3 has a very dense structure in comparison with a surface layer not irradiated with laser beam, the mechanical strength of the Al₂O₃ spray coating 3 is improved, and the durability to an external force acting on the mounting member 16 is remarkably improved.

In the case of the original Al₂O₃ spray coating not irradiated with laser beam, if external force is applied, Al₂O₃ particles are detached from each other at boundaries existing between the particles and hence coating particles easily drop out. When the high-strength ceramic layer 5 is formed in the surface layer 4 of the Al₂O₃ spray coating 3 as in this embodiment, dropout of the coating particles due to existence of boundaries between Al₂O₃ particles can be reduced. Of course, the dropout of particles generated from the base member 2 coated with the Al₂O₃ spray coating 3 can also be reduced. The effect of reducing the dropout of coating particles and base member particles by the formation of the high-strength ceramic layer 5 of this embodiment is sufficient for providing the good semiconductor manufacturing process, and the dropout of the particles can be prevented from affecting the process.

The thickness of the high-strength ceramic layer 5 is preferable to be not more than 200 μm. When the high-strength ceramic layer 5 has a thickness of more than 200 μm, the residual stress of the remelted and resolidified surface layer becomes excessively large, and impact resistance to an external force is deteriorated, leading to rather decrease the mechanical strength. In addition, it is required to increase the output of laser beam or to take a long scanning time, which is inefficient and brings about the increase of production costs.

The average porosity of the high-strength ceramic layer 5 is preferably less than 5%, more preferably less than 2%. That is, it is important that a porous layer having an average porosity of 5 to 10% in the surface layer 4 of the Al₂O₃ spray coating 3 is made to a densified layer having an average porosity of less than 5% by the irradiation of laser beam, whereby there can be obtained the sufficiently densified high-strength ceramic layer 5 being less in the boundaries between Al₂O₃ particles.

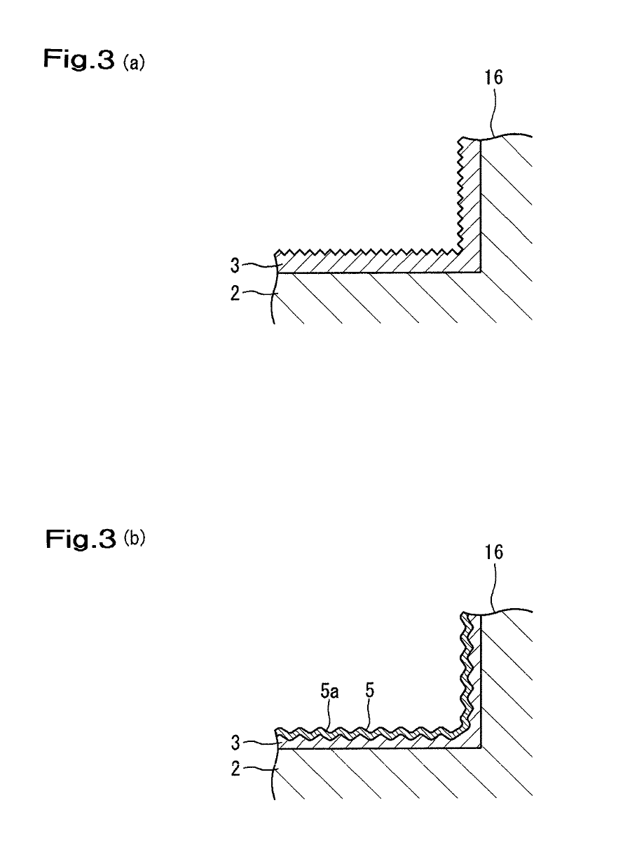

FIG. 3(a) is a schematically sectional view of the mounting member 16 coated with the Al₂O₃ spray coating 3 and subjected to finish grinding, and FIG. 3(b) is a schematically sectional view after the irradiation of laser beam. The surface 5a of the high-strength ceramic layer 5 has a surface roughness of not more than 2.0 μm in terms of Ra value by the irradiation of laser beam. When the surface roughness is in such a range, action of an excessively strong force on the high-strength ceramic layer 5 can be prevented, for example, even if the wafer 52 is rubbed, and the dropout of the coating particles can be accordingly reduced.

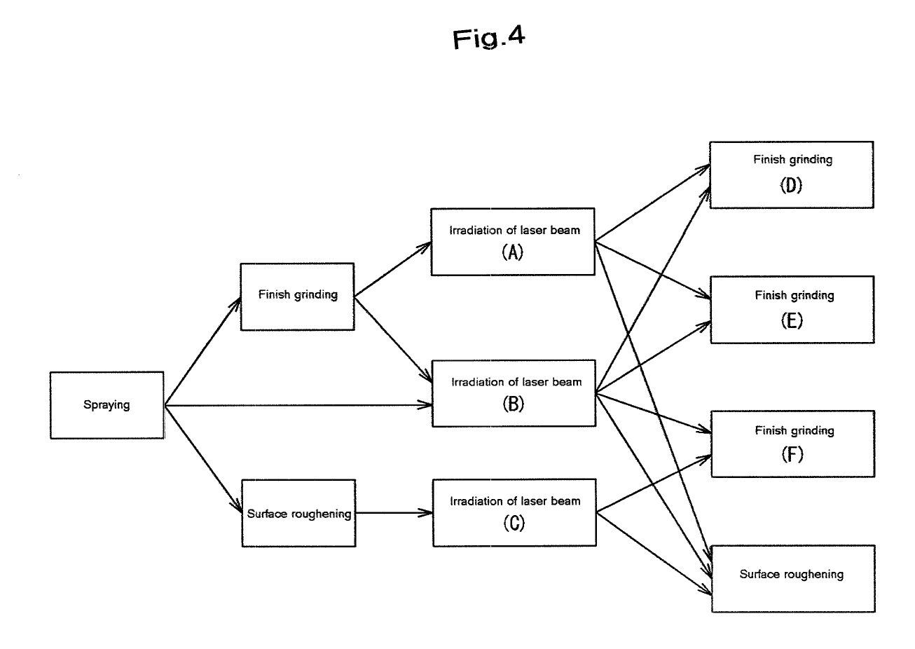

FIG. 4 is a process chart for adjusting the surface roughness. The process for adjusting the surface roughness is divided into a spraying step, a surface treating step after spraying, a step of irradiating laser beam and a surface treating step after the irradiation of laser beam. The surface roughness after spraying is, for example, about 4 to 6 μm in terms of Ra value, but such a roughness is not required to be strictly adjusted. The surface treating step after spraying includes finish grinding and surface roughening. As the finish grinding are included grinding with a grindstone and polishing with a LAP, where the surface roughness is adjusted to, for example, about 0.2 to 1.0 μm in terms of Ra value. As the surface roughening are mentioned formation of fine irregularities by blasting and formation of larger irregularities or embossment by machining, where the surface roughness is adjusted to, for example, not less than 1.0 μm in terms of Ra value.

The surface roughness after the irradiation of laser beam is divided into, for example, (A) 0.4 to 2.0 μm, (B) 2.0 to 10.0 μm and (C) not less than 10.0 μm in terms of Ra value. The surface treating step after the irradiation of laser beam includes finish grinding and surface roughening. The finish grinding is divided, for example, into (D) adjustment of the surface roughness to about 0.1 to 0.4 μm in terms of Ra value to make the surface flattest, (E) adjustment of the surface roughness to not less than 0.4 μm to roughen the surface and (F) flattening of only a top part after roughening. As the surface roughening are mentioned formation of fine irregularities by blasting and formation of larger irregularities or embossment by machining. For example, in order to prevent component transfer or heat conduction from the mounting member 16 to the wafer 52, the steps of FIG. 4 are combined by considering various requirements inclusive of reduction of a contact area between the mounting member 16 and the wafer 52, whereby the surface roughness of the surface 5a of the high-strength ceramic layer 5 is adjusted to an appropriate value.

As shown in FIG. 2, a crack 6 of network form as a whole is formed in the high-strength ceramic layer 5. The crack 6 results from resolidification of the surface layer 4 of the Al₂O₃ spray coating 3 and is formed by shrinkage of the surface layer 4 in the solidification from a melted state. The width of the crack 6 is preferable to be not more than 10 μm, and is often less than 1 μm really. Here, the width refers to a width of an opening portion of the crack 6. The edge of the crack 6 does not protrude from the surface 5a of the high-strength ceramic layer 5. Therefore, the presence of the crack 6 does not increase a frictional force between the high-strength ceramic layer 5 of the surface layer 4 and the wafer 52, and the coating particles dropped out due to the abrasion of the high-strength ceramic layer 5 are not increased.

The net-like crack 6 is formed by linkage of a large number of small cracks 7. The interval between the small cracks 7 is not more than 1 mm, and mostly about 0.1 mm in this embodiment. Since the crack 6 is net-like, the crack 6 is hard to extend any more, and does not grow. Consequently, a change in properties of the high-strength ceramic layer 5 over time is suppressed, and a reduction in the mechanical strength of the high-strength ceramic layer 5 resulting from the crack 6 is prevented. Further, since the crack 6 is net-like, the crack 6 acts as a buffer mechanism to thermal stress applied to the high-strength ceramic layer 5, and hence breakage or peeling of the high-strength ceramic layer 5 can be prevented. Moreover, the crack 6 is not required to have the large number of small cracks 7 completely linked together, but may be substantially net-like as a whole.

One network region 12 constituting the net-like crack 6 forms any form such as a rectangular form, a hexagonal form or the like. Each of at least 90% network regions among many network regions 12 constituting the crack 6 has a size falling within an imaginary circle having a diameter of about 1 mm. In other words, each of 90 regions among 100 network regions 12, for example, existing in a certain range has a size falling within an imaginary circle having a diameter of about 1 mm, while each of the other 10 network regions 12 has a size and a form of partially protruding from the imaginary circle having a diameter of about 1 mm outward. Since the large number of network regions 12 are sized as described above, the buffer mechanism to thermal stress can be effected surely.

The width of the crack 6 (gap interval between the network regions 12) and the size of the network region 12 can be controlled by changing conditions for the irradiation of laser beam. That is, when the amount of the Al₂O₃ spray coating 3 melted at one time is increased and the cooling speed is made slow, the width of the crack 6 and the size of the network region 12 tend to become large, and when the conditions are reversed, the width of the crack 6 and the size of the network region 12 tend to become small. Therefore, when the output and the spot diameter of laser beam are made large and the scanning speed is made small, the width of the crack 6 and the size of the network region 12 become large, and when the output and the spot diameter of laser beam are made small and the scanning speed is made large, the width of the crack 6 and the size of the network region 12 become small.

As shown in FIG. 2, the crack 6 deeply extends through the high-strength ceramic layer 5 to a non-recrystallized layer 8 in the Al₂O₃ spray coating 3. When the crack 6 extends to the non-recrystallized layer 8 in the Al₂O₃ spray coating 3, action as a buffer mechanism to thermal stress applied to the high-strength ceramic layer 5 is enhanced, and the effect of preventing breakage or peeling of the high-strength ceramic layer 5 can be improved.

The irradiation of laser beam is performed by scanning laser beam on the Al₂O₃ spray coating 3 formed in the mounting member 16. The scanning of laser beam may be performed by a well-known method such as a method of conducting the scanning with a galvano scanner or the like, a method of fixing a transfer arm as a scanning object to an X-Y stage and moving the arm in X and Y directions or the like. Since the irradiation of laser beam can be conducted in air, deoxidation phenomenon of Al₂O₃ is reduced. Depending on irradiation conditions of laser beam may be caused deoxidation phenomenon even in air to blacken the spray coating. In such a case, the deoxidation phenomenon can be avoided to prevent blackening by blowing oxygen during the irradiation of laser beam or by surrounding the periphery with a chamber or the like to create an atmosphere of high oxygen partial pressure. By adjusting these various conditions can be lowered the lightness of the Al₂O₃ spray coating 3 or the Al₂O₃ spray coating 3 can be kept white.

In the irradiation of laser beam, it is preferable to use a CO₂ gas laser or a YAG laser. As conditions for the irradiation of laser beam are recommended the following conditions: laser output: 5 to 5000 W; laser beam area: 0.01 to 2500 mm²; and treatment speed: 5 to 1000 mm/s.

The surface of the Al₂O₃ spray coating may be irradiated with an electron beam to form a high-strength ceramic layer on the surface layer of the spray coating. In this case, the resulting high-strength ceramic layer has performances comparable to those of the aforementioned ceramic layer, and the mechanical strength of the Al₂O₃ spray coating is improved and the durability to the external force applied on the mounting member 16 is remarkably improved. As conditions for the irradiation of electron beam are recommended the following conditions: irradiation atmosphere: Ar gas of 10 to 0.005 Pa; irradiation output: 10 to 10 KeV; and irradiation speed: 1 to 20 m/s.

In the transfer arm 1 of this embodiment, the mounting member 16 can be made durable to the action of various forces because the high-strength ceramic layer 5 made of an Al₂O₃ recrystallized material modified by remelting and resolidifying Al₂O₃ is formed on the surface layer 4 of the Al₂O₃ spray coating 3 formed on the mounting member 16, whereby the surface layer 4 is rendered into a dense layer structure to improve the mechanical strength of the Al₂O₃ spray coating 3.

Therefore, when the speed of the transfer arm 1 is increased for the improvement of production efficiency, even if forces tremblingly contacting with the wafer are applied by minute vibrations associated therewith, or forces contacting with the wafer are increased at the time of driving and stopping, the coating particles dropped out from the Al₂O₃ spray coating 3 and the base member particles dropped out from the base member 2 can be surely reduced to an extent not affecting the semiconductor manufacturing process, and the generation of particles can be sufficiently reduced. Further, since the Al₂O₃ spray coating 3 is used, no component contamination occurs because of the absence of impurity components, and the manufacture can be performed at lower costs.

In the present invention is used the ceramic-thermal spray coating, so that the application of the present invention is not limited depending on the size of the member for semiconductor manufacturing device, and the present invention is applicable to not only the relatively small member as mentioned above but also large members. Although the Al₂O₃ spray coating is formed as the ceramic spray coating in the above embodiment, a high-strength ceramic layer having a dense layer structure is formed in a similar fashion even if the other oxide-based ceramics, nitride-based ceramics, carbide-based ceramics, fluoride-based ceramics, boride-based ceramics and mixtures thereof are used, whereby the coating particles dropped out from the ceramic spray coating and the base member particles dropped out from the base member can be surely reduced to an extent not affecting the semiconductor manufacturing process, and the generation of particles can be sufficiently reduced.

When the present invention is applied to an electrostatic chuck being the other member for semiconductor manufacturing device to form a high-strength ceramic layer made of a ceramic recrystallized material modified by remelting and resolidifying a ceramic composition on a surface layer of a ceramic spray coating formed in the electrostatic chuck, the coating particles dropped out from the ceramic spray coating or the base member particles dropped out from the base member can be surely reduced to an extent not affecting the semiconductor manufacturing process and the generation of particles can be sufficiently reduced even if forces from a wafer by collision due to detachment of the wafer, friction by thermal expansion and shrinkage of the wafer and pressing of the wafer, or other relatively strong forces are applied. Therefore, the number of backside particles generated at the back surface of the wafer by contacting the wafer with the electrostatic chuck can be decreased. As the number of backside particles is decreased, local elevation of the wafer, decrease in the flatness of the wafer, and decrease in degree of adhesion between the wafer and the electrostatic chuck can be suppressed to reduce occurrence of defects resulted from the particles.

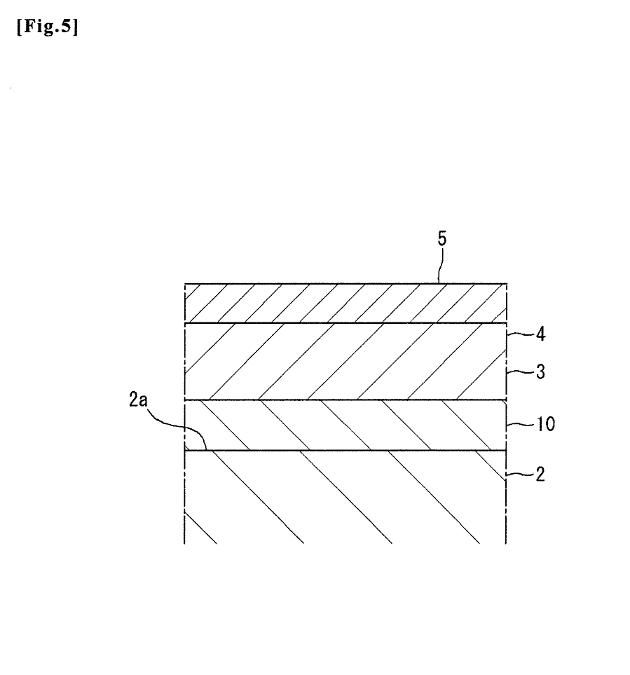

FIG. 5 is a schematically sectional view of a mounting member according to another embodiment in the vicinity of its surface. This embodiment is different from the aforementioned embodiment in a point that an undercoat layer 10 is formed between the base member 2 and the Al₂O₃ spray coating 3. The surface layer 4 of the Al₂O₃ spray coating 3 is provided with the same high-strength ceramic layer 5 as in the aforementioned embodiment. The undercoat layer 10 is formed by a spraying method, a vapor deposition method or the like.

As a material of the undercoat layer is preferable one or more selected from the group consisting of metals such as Ni, Al, W, Mo, Ti and the like, alloys containing one or more of the metals, ceramics such as oxides, nitrides, borides and carbides of the metals, cermet composed of the above ceramic and metal and cermet composed of the above ceramic and alloy.

By the formation of the undercoat layer 10 can be shielded the surface 2a of the base member 2 from corrosive environment to improve the corrosion resistance of the mounting member and further improve adhesion between the base member 2 and the Al₂O₃ spray coating 3. Moreover, the thickness of the undercoat layer 10 is preferable to be about 50 to 500 μm. When the thickness of the undercoat layer 10 is less than 20 μm, sufficient corrosion resistance is not obtained, and uniform coating formation is difficult, while even if the thickness is more than 500 μm, effects on the corrosion resistance and adhesion are same, and rather costs are increased.

### EXAMPLES

The present invention will be described more in detail by way of an example below. The present invention is not limited to examples mentioned later. A test piece 1 is prepared by coting one-sided surface of a flat plate A 6061 of 100×100×5 mm with an Al₂O₃ spray coating of 200 μm in thickness through a plasma spraying method and grinding the surface thereof with a #400 diamond grindstone. A test piece 2 is prepared by coating one-sided surface of a flat plate A 6061 of 100×100×5 mm with an Al₂O₃ spray coating of 200 μm in thickness through a plasma spraying method, grinding the surface thereof with a #400 diamond grindstone and further irradiating with laser beam. In the spraying, Ar and H₂ are used as a plasma gas and a plasma output is set to 30 kW. The irradiation of laser beam is performed under conditions of output: 5 W; laser beam area: 0.03 mm²; and treatment speed: 10 mm/s.

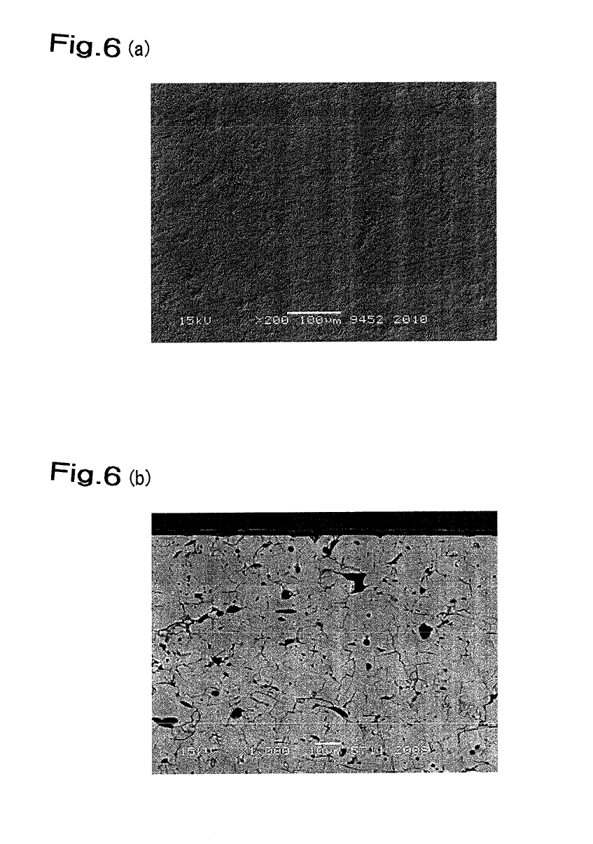

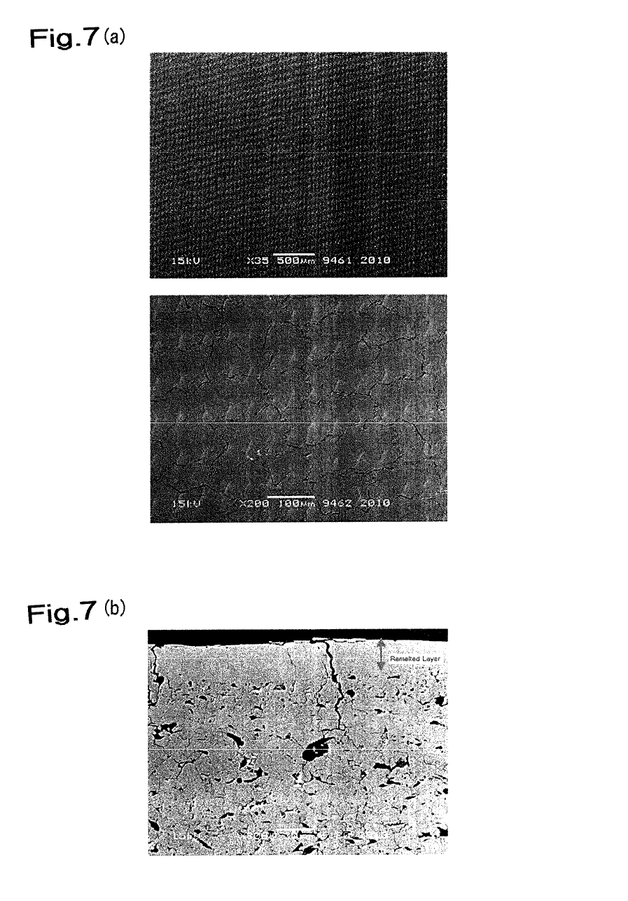

FIG. 6(a) is an electron microscope photograph of the surface of the test piece 1, and FIG. 6(b) is an electron microscope photograph of a cross section of a surface layer thereof. FIG. 7(a) is an electron microscope photograph of the surface of the test piece 2, and FIG. 7(b) is an electron microscope photograph of a cross section of a surface layer thereof. A crack is net-like, and a large number of network regions constituting the net-like crack are formed in a rectangular shape, a hexagonal shape or the like, and each of at least 90% network regions thereof has a size falling within an imaginary circle having a diameter of about 0.3 mm. The crack of a high-strength ceramic layer extends to a non-recrystallized layer in the Al₂O₃ spray coating. The surface of the test piece 1 not irradiated with laser beam is rough and not smooth. After the irradiation with laser beam, minute undulations associated with the scanning of laser beam are existent on the surface of the high-strength ceramic layer, but have almost no sharp parts, so that such a surface is very smooth and dense. Therefore, even if an external force is applied onto the high-strength ceramic layer forming the surface layer of the Al₂O₃ spray coating, micro breakage is hard to occur, and the dropout of the coating particles can be reduced.

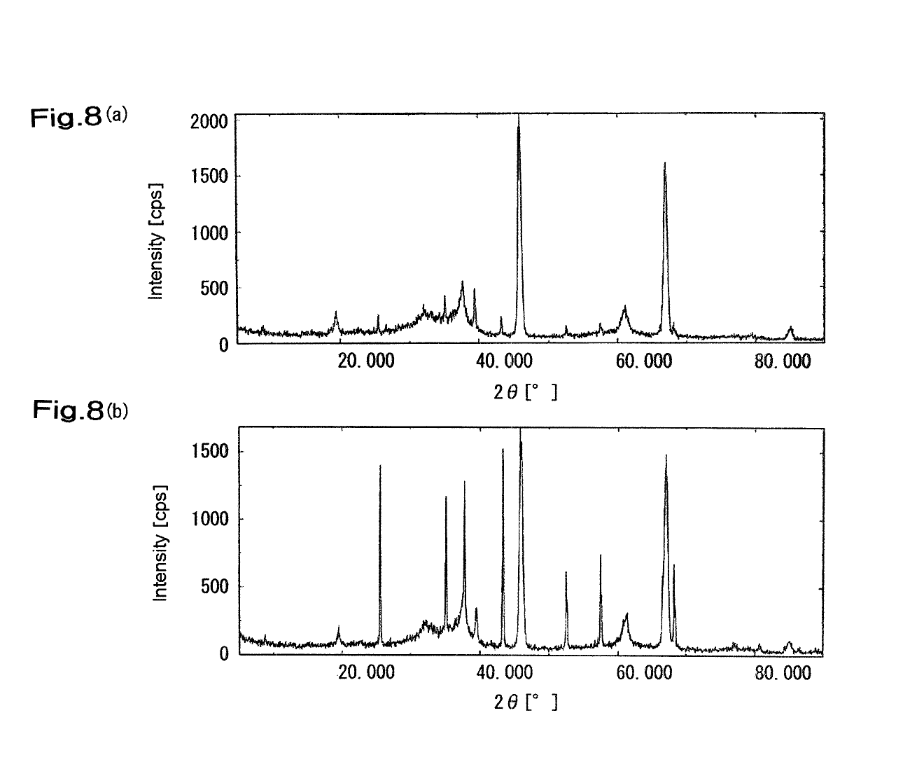

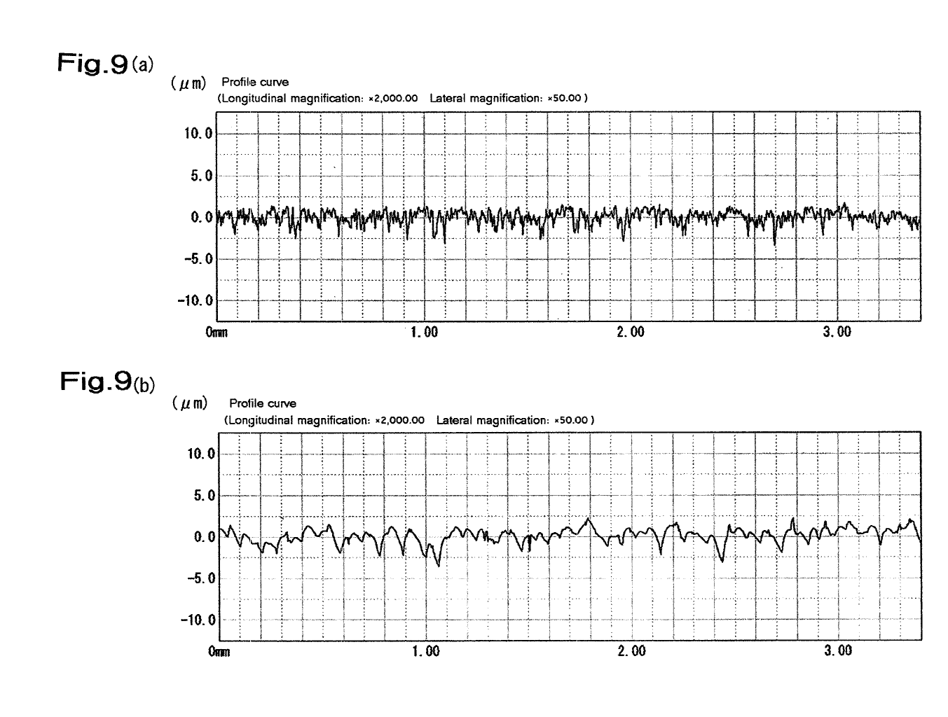

FIG. 8(a) is an X-ray analysis chart of the surface layer of the Al₂O₃ spray coating in the test piece 1, and FIG. 8(b) is an X-ray analysis chart of the surface layer of the Al₂O₃ spray coating in the test piece 2. The crystal structure of the Al₂O₃ spray coating in the test piece 1 is in a mixed state of α-type and γ-type. The crystal structure of the surface layer of the Al₂O₃ spray coating in the test piece 2 irradiated with laser beam is mostly α-type, and the formation of the high-strength ceramic layer is recognized. FIG. 9(a) is a chart showing a surface roughness of the Al₂O₃ spray coating in the test piece 1, and FIG. 9(b) is a chart showing a surface roughness of the Al₂O₃ spray coating in the test piece 2. The surface of the Al₂O₃ spray coating in the test piece 2 irradiated with laser beam is recognized to be slightly smooth because it is melted.

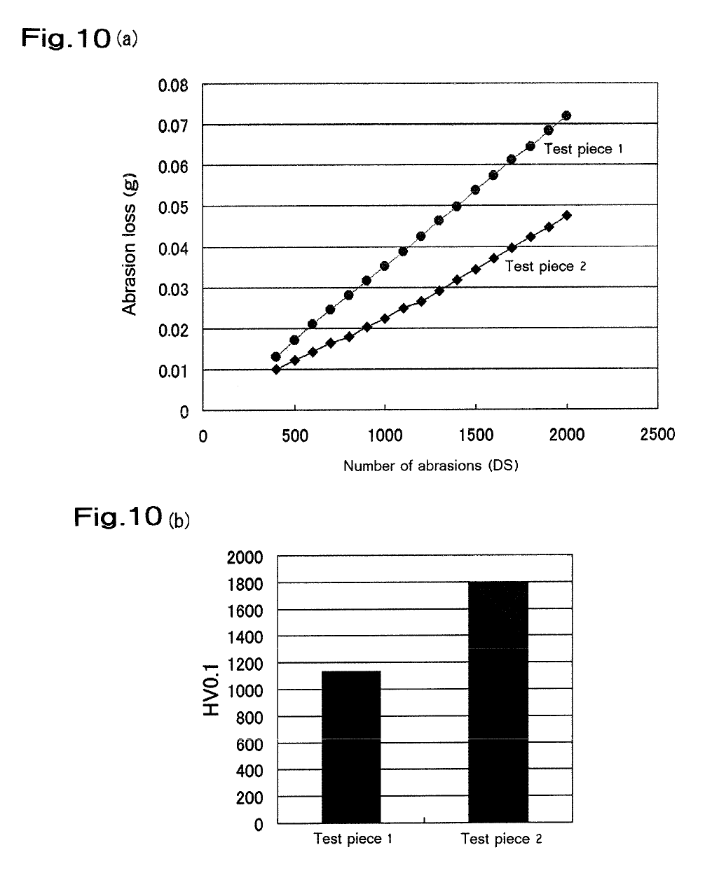

The abrasion resistance and the hardness are compared between the test piece 1 and the test piece 2. The abrasion resistance is evaluated by a Suga system abrasion test. An abrasion loss is measured under conditions for the abrasion test of load: 3.25 kgf; abrasive paper: GC#320; and number of reciprocations: 2000. The test results are shown in FIG. 10(a). The test piece 2 having the high-strength ceramic layer formed by the irradiation of laser beam is less in the abrasion loss and improved the abrasion resistance as compared to the test piece 1 not irradiated with laser beam.

The hardness is evaluated by a Vickers hardness test according to JIS Z 2244. Conditions for the hardness test are as follows: load: 0.1 kgf; and measurement points: 10 points. The average value at measuring points of 1 to 10 is calculated. The test results are shown in FIG. 10(b). The test piece 2 having the high-strength ceramic layer formed by the irradiation of laser beam is higher in the Vickers hardness as compared to the test piece 1 not irradiated with laser beam, from which is recognized that the hardness is enhanced by the irradiation of laser beam.

Next, a plurality of test pieces with different crack widths are prepared, and a pressing test is conducted for examining chipping of a high-strength ceramic layer and degree of wafer damage when a wafer is pressed thereto. The chipping of the high-strength ceramic layer and the wafer damage are caused by concentration of load on corners of a crack, and the wafer damage is also caused by particles associated with the chipping of the high-strength ceramic layer. As the width of the crack becomes too large, the load is concentrated in the corners of the crack to chip the high-strength ceramic layer, so that particles are easily generated. The wafer is damaged by the concentration of load and the generation of particles.

The thickness of the high-strength ceramic layer is set to 20 μm, and a wafer of 0.7 mm is pressed onto the surface of the high-strength ceramic layer under a pressure of 14 kPa. The width of the crack can be controlled by changing conditions for the irradiation of laser beam as described above. Test pieces with crack widths of 1 μm, 2 μm, 5 μm, 10 μm and 20 μm are prepared, and the pressing test is conducted with each of the test pieces. The test piece with a crack width of 1 μm is identical to the test piece 2, and each of the test pieces with crack widths of 2 μm, 5 μm, 10 μm and 20 μm is obtained by gradually increasing the output and laser beam area and gradually decreasing the treatment speed among the conditions for the irradiation of laser beam in the test piece 2. As a result, the wafer damage is not observed in any of the test pieces, but the chipping of the high-strength ceramic layer is observed in the test piece with a crack width of 20 μm.

Next, a plurality of test pieces with different sizes of network region are prepared, and a thermal expansion test is conducted for examining dropout of network regions (high-strength ceramic layer) at the time of heating. The dropout of the network region in the heating is caused by peeling due to the fact that the network region cannot follow deformation due to thermal expansion and shrinkage of a non-high-strength ceramic layer. When the size of the network region is large, the network region is hard to follow the deformation due to the thermal expansion and shrinkage of the non-high-strength ceramic layer, while when the size of the network region is small, the deformation due to the thermal expansion and shrinkage of the non-high-strength ceramic layer can be absorbed by a gap between network regions (crack part), and hence the network regions are hardly peeled off.

The thickness of the high-strength ceramic layer is set to 20 μm, and the heating temperature is set to 150° C. The size of the mesh region can be controlled by changing the conditions for the irradiation of laser beam as described above. Test pieces with network region sizes of φ0.2, φ0.5, φ1.0 and φ2.0 at maximum are prepared, and the thermal expansion test is conducted with each of the test pieces. The test piece with a network region size of φ0.2 at maximum is identical to the test piece 2, and the test pieces with network region sizes of φ0.5, φ1.0 and φ2.0 at maximum are obtained by gradually increasing the output and laser beam area and gradually decreasing the treatment speed among the conditions for the irradiation of laser beam in the test piece 2. As a result, the dropout of network regions is slightly observed in the test piece with a network region size of φ0.2 at maximum, but the dropout of network regions is not observed in the test pieces with network region sizes of φ0.5, φ1.0 and φ2.0 at maximum.

The embodiments and examples disclosed above are illustrative and not restrictive. Ceramic spray coatings made from various kinds of materials can be employed as described above. For example, in the case of the Y₂O₃ spray coating, a high-strength ceramic layer having the same configuration as in the above embodiments can be formed. The opening portion of the crack formed, for example, on the surface of the high-strength ceramic layer may be sealed, and in this case, the dropout of particles through the crack can be prevented. The above embodiments are described by showing as an example a case where the wafer is in contact with the ceramic spray coating, but the present invention can also be applied to a case that a glass base member is in contact with a ceramic spray coating, whereby backside particles of the glass base member can be reduced. The transfer arm includes not only a type of merely placing a wafer but also a type of absorbing a wafer, a type of mechanically catching a wafer and a type of sandwiching an edge of a wafer. The member for semiconductor manufacturing device according to the present invention can be applied not only to the transfer arm but also to a wafer gripping member or a glass base member gripping member such as an electrostatic chuck, a vacuum chuck, a mechanical chuck or the like, and various kinds of other members such as a lift pin and the like.

After the high-strength ceramic layer is formed on the ceramic spray coating, the surface state may be adjusted by machining, blasting or the like. The desired minute shape may be intentionally created by combination of a spot diameter and a scanning pitch of a laser beam, dot drawing by pulse irradiation, pattern drawing by ON/OFF control of laser beam irradiation, or the like. Further, the surface state may be adjusted by machining or blasting after the minute shapes are created. Alternatively, a specific shape may be formed on the surface by giving an embossed shape before the irradiation of laser beam, irradiating laser beam thereto and performing the machining or blasting.

### DESCRIPTION OF REFERENCE SYMBOLS

1 Transfer arm

2 Base member

3 Al₂O₃ spray coating

4 Surface layer

5 High-strength ceramic layer

6 Crack

8 Non-recrystallized part

10 Undercoat layer

12 Network region

16 Mounting member

1. A member for semiconductor manufacturing device comprising a base member for forming a semiconductor manufacturing device, and a ceramic spray coating applied on a surface of the base member, characterized in that a surface layer of the ceramic spray coating is provided with a high-strength ceramic layer for reducing particles dropped out from the member for semiconductor manufacturing device due to external factors in the semiconductor manufacturing device to an extent not affecting a semiconductor manufacturing process, and the high-strength ceramic layer is made from a ceramic recrystallized material formed by spraying a ceramic onto the surface of the base member to form a thermal spray coating and then irradiating the surface thereof with a laser beam or an electron beam to remelt and resolidify a ceramic composition of the surface layer of the thermal spray coating for modification, and a net-like crack is formed in the high-strength ceramic layer.

2. The member for semiconductor manufacturing device according to claim 1, wherein each of at least 90% network regions among a large number of network regions constituting the net-like crack has a size falling within an imaginary circle having a diameter of about 1 mm.

3. The member for semiconductor manufacturing device according to claim 1, wherein the crack extends to a non-recrystallized layer in the ceramic spray coating.

4. The member for semiconductor manufacturing device according to claim 1, wherein an opening portion of the crack is sealed.

5. The member for semiconductor manufacturing device according to claim 1, wherein the high-strength ceramic layer has a thickness of not more than 200 μm.

6. The member for semiconductor manufacturing device according to claim 1, wherein the high-strength ceramic layer has a surface roughness of not more than 2.0 μm in terms of Ra value.

7. The member for semiconductor manufacturing device according to claim 1, wherein the ceramic spray coating is made from one or more materials selected from the group consisting of oxide-based ceramics, nitride-based ceramics, carbide-based ceramics, fluoride-based ceramics and boride-based ceramics.

8. The member for semiconductor manufacturing device according to claim 7, wherein the oxide-based ceramic is either one of alumina and yttria or a mixture thereof.

9. The member for semiconductor manufacturing device according to claim 1, wherein the particles are backside particles generated at a back surface of a wafer or a back surface of a glass base member when the wafer or the glass base member comes into contact with the ceramic spray coating.

10. The member for semiconductor manufacturing device according to claim 1, wherein the member for semiconductor manufacturing device is a wafer gripping member or a glass base member gripping member.
